(19) United States
(12) Patent Application Publication
(10) Pub. No.: US 2014/0225123 A1
(43) Pub. Date: Aug. 14, 2014

(54) REO/ALO/AlN TEMPLATE FOR III-N MATERIAL GROWTH ON SILICON

(71) Applicants: Erdem Arkun, Campbell, CA (US); Michael Lebby, Apache junction, AZ (US); Andrew Clark, Los Altos, CA (US); Rytis Dargis, Fremont, CA (US)

(72) Inventors: Erdem Arkun, Campbell, CA (US); Michael Lebby, Apache junction, AZ (US); Andrew Clark, Los Altos, CA (US); Rytis Dargis, Fremont, CA (US)

(21) Appl. No.: 14/180,079

(22) Filed: Feb. 13, 2014

Related U.S. Application Data
(63) Continuation-in-part of application No. 13/717,211, filed on Dec. 17, 2012.

(51) Int. Cl. H01L 33/46; H01L 33/32; H01L 33/00

(52) U.S. Cl. CPC H01L 33/46; H01L 33/007; H01L 33/32
USPC 257/76; 438/29

(57) ABSTRACT

A III-N template formed on a silicon substrate includes a Distributed Bragg Reflector positioned on the silicon substrate. The Distributed Bragg Reflector is substantially crystal lattice matched to the surface of the silicon substrate. An aluminum oxide layer is positioned on the surface of the Distributed Bragg Reflector and substantially crystal lattice matched to the surface of the Distributed Bragg Reflector. A layer of aluminum nitride (AlN) is positioned on the surface of the aluminum oxide layer and substantially crystal lattice matched to the surface of the aluminum oxide layer. A III-N LED structure including at least one III-N layer can then be grown on the aluminum nitride layer and substantially crystal lattice matched to the surface of the aluminum nitride layer.

### FIELD OF THE INVENTION

This invention relates in general to the formation of a template for the growth of GaN on a silicon substrate and more specifically to the formation of a DBR as the REO in a REO/aluminum oxide/aluminum nitride template.

### BACKGROUND OF THE INVENTION

In the semiconductor industry, it is known that growing a III-N material, such as GaN, on a silicon substrate is difficult due in large part to the large crystal lattice mismatch (−16.9%) and the thermal mismatch (53%) between silicon and GaN. It is also known that LED devices built on silicon substrates suffer from absorption of emitted light by the silicon substrate. Thus, some type of buffer layer or layers is generally formed on the silicon substrate and the III-N material is grown on the buffer layer. It is also known that during much of the growth process there must ideally be no exposed silicon surface due to detrimental reaction between silicon and the various MBE process gasses, i.e. N₂ plasma, NH₃ and metallic Ga. Also in the case where other growth processes are used, such as MOCVD process gasses (NH₃, H₂, TMGa, etc.). Reaction of silicon with process gasses usually results in etching of silicon (H₂), formation of nitrides (NH₃), or severe reaction and blistering (Ga precursors).

In the prior art, one method of solving the light absorption problem is to fabricate the LED on a silicon substrate and then bond the finished LED on a reflective coating and remove the silicon substrate. Generally, the top layer of the resulting structure is roughened to improve light extraction efficiency. However, this is a long and work intensive process.

It would be highly advantageous, therefore, to remedy the foregoing and other deficiencies inherent in the prior art.

Accordingly, it is an object of the present invention to provide new and improved methods for the formation of a REO/aluminum oxide/aluminum nitride template on a silicon substrate.

It is another object of the present invention to provide new and improved methods for the formation of a template that includes eliminating or greatly reducing the problem of possible damage to the silicon substrate with process gasses.

It is another object of the present invention to provide a new and improved REO/aluminum oxide/aluminum nitride template on a silicon substrate.

It is another object of the present invention to provide new and improved LED structures on a template on a silicon substrate.

It is another object of the present invention to provide a new and improved DBR/aluminum oxide/aluminum nitride template on a silicon substrate.

### SUMMARY OF THE INVENTION

Briefly, the desired objects and aspects of the instant invention are also realized in accordance with a specific crystal lattice matched template on a single crystal silicon substrate. The template includes a Distributed Bragg Reflector positioned on the silicon substrate. The Distributed Bragg Reflector is substantially crystal lattice matched to the surface of the silicon substrate. An aluminum oxide layer is positioned on the surface of the Distributed Bragg Reflector and substantially crystal lattice matched to the surface of the Distributed Bragg Reflector. A layer of aluminum nitride (AlN) is positioned on the surface of the aluminum oxide layer and substantially crystal lattice matched to the surface of the aluminum oxide layer. A III-N LED structure including at least one III-N layer can then be grown on the aluminum nitride layer and substantially crystal lattice matched to the surface of the aluminum nitride layer. The DBR redirects all downwardly directed light from the LED upwardly to substantially improve the efficiency of the LED.

The desired objects and aspects of the instant invention are further achieved in accordance with a preferred method of fabricating a template on a silicon substrate including the steps of providing a single crystal silicon substrate and epitaxially growing a Distributed Bragg Reflector on the silicon substrate. The Distributed Bragg Reflector is substantially crystal lattice matched to the surface of the silicon substrate. The method further includes the steps of epitaxially growing an aluminum oxide layer on the surface of the Distributed Bragg Reflector substantially crystal lattice matched to the surface of the Distributed Bragg Reflector and epitaxially growing a layer of aluminum nitride (AlN) on the surface of the aluminum oxide layer substantially crystal lattice matched to the surface of the aluminum oxide layer. A III-N LED structure including at least one III-N layer can then be epitaxially grown on the aluminum nitride layer and substantially crystal lattice matched to the surface of the aluminum nitride layer. The DBR redirects all downwardly directed light from the LED upwardly to substantially improve the efficiency of the LED.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram of a template on a silicon substrate, in accordance with the present invention;

FIG. 2 is a simplified layer diagram of the template of FIG. 1 with an LED structure formed thereon;

FIG. 3 is a simplified layer diagram of the template of FIG. 1 with an HEMT structure formed thereon;

FIG. 4 is a simplified layer diagram of a DBR on a silicon substrate, in accordance with the present invention;

FIG. 5 is a chart illustrating different materials and the indexes of refraction; and

FIG. 6 is a simplified layer diagram of a template with an LED in accordance with the present invention.

### DETAILED DESCRIPTION OF THE DRAWINGS

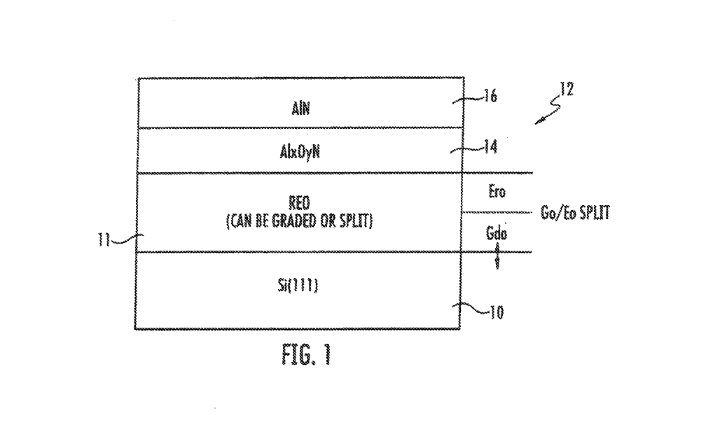

Turning to FIG. 1, a simplified layer diagram is illustrated representing several steps in a process of forming a template 12 on a silicon substrate 10, in accordance with the present invention. It will be understood that substrate 10 is or may be a standard well known single crystal wafer or portion thereof generally known and used in the semiconductor industry. Single crystal substrates, it will be understood, are not limited to any specific crystal orientation but could include (111) silicon, (110) silicon, (100) silicon or any other orientation or variation known and used in the art. The Si (100) and (111) substrates could also include various miscuts with nominal value between 0 and 10° in any direction. In the present invention a (111) silicon single crystal substrate is preferred because of the simplicity of further epitaxial growth.

A layer 11 of rare earth oxide (REO) is epitaxially grown on silicon substrate 10. Various rare earth oxides have a crystal lattice spacing that can be matched to silicon with very little strain. For example, Gd₂O₃ has a crystal lattice spacing (a) of 10.81 Å, Er₂O₃ has a crystal lattice spacing (a) of 10.55 Å, Nd₂O₃ has a crystal lattice spacing (a) of 11.08 Å, and silicon has a double spacing (2a) of 10.86 Å. Further, the crystal lattice spacing of REO layer 11 can be varied by varying the composition of the constituents, which allows for strain engineering of the silicon wafers. Generally, the REO material closest to or adjacent silicon substrate 10 will have a crystal spacing closest to the crystal spacing of silicon while REO materials adjacent the opposite side of layer 11 will have a crystal spacing closer to the crystal spacing of materials grown on the surface. Strain engineering mitigates the stresses formed during growth of III-N materials on these substrates.

In a typical example, layer 11 includes Gd₂O₃ epitaxially grown on silicon substrate 10 with Er₂O₃ epitaxially grown adjacent the opposite (upper) side. The REO materials can be grown in a graded fashion bridging the two compositions or split to have an abrupt change in the composition and/or constituents of layer 11. Also, while two constituents are used in this example other and/or additional rare earth oxides can be included in layer 11.

A layer 14 of aluminum oxide is grown on the surface of REO layer 11. Aluminum oxide layer 14 is grown epitaxially and is mostly single crystal material substantially crystal lattice matched to silicon substrate 10. It will be understood that Al₂O₃ is the normal proportion required (stoichiometric) but non-stoichiometric compounds (e.g. Al₂₋ₓO_{3-y}) may be used in specific applications. Also, aluminum oxide layer 14 may include aluminum oxynitride (AlₓO_{y}N), which is intended to come within the definition of “aluminum oxide” for purposes of this invention.

It should be noted that REO materials and aluminum oxide are impervious to MBE process gasses, i.e. N₂ plasma, NH₃ and metallic Ga, which is the preferred growth process in this invention. Also, in the event that other growth processes are used, such as the MOCVD process, the aluminum oxide is also impervious to MOCVD process gasses (NH₃, H₂, TMGa, etc.). Reaction of silicon with process gasses usually results in etching of silicon (H₂), formation of nitrides (NH₃), or severe reaction and blistering (Ga precursors). Thus silicon substrate 10 is protected from damage caused by generally all growth process gasses by both REO layer 11 and aluminum oxide layer 14. Preferably, aluminum oxide layer 14 is a few nanometers (nm) thick but for certain applications thicker or thinner films can be grown. Also, aluminum oxide layer 14 can be formed with a single continuous composition or it can be graded, in linear, stepwise or any similar schemes.

An aluminum nitride (AlN) layer 16 is epitaxially grown on aluminum oxide layer 14 preferably by an MBE process. The combination of aluminum oxide layer 14 and aluminum nitride layer 16 results in a base for the further growth of III-N materials. REO layer 11, aluminum oxide layer 14, and aluminum nitride layer 16 form template 12 which substantially crystal lattice matches the III-N materials to the silicon substrate and greatly reduces any thermal mismatch. Also, template 12 imparts chemical stability to the process due to the nature of the materials.

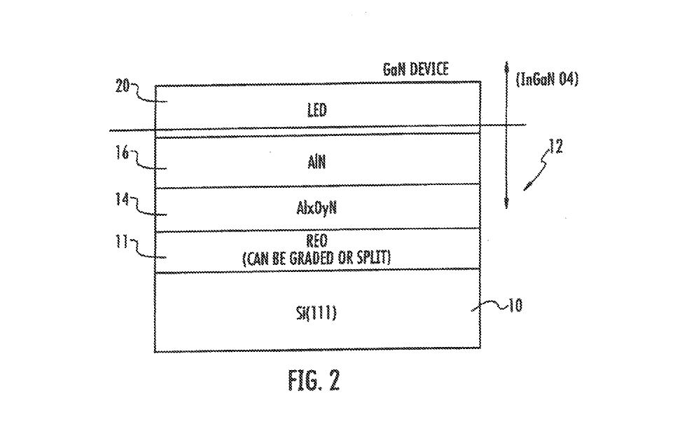

Turning to FIG. 2, template 12 is illustrated with a III-N LED structure 20 formed thereon. Structure 20 is illustrated as a single layer for convenience but it should be understood that III-N LED structure 20 includes the growth of one or more typical layers, including for example, i-GaN, n-GaN, active layers such as InGaN/GaN, electron blocking layers, p-GaN, and other inter-layers used in the formation and performance of LED (especially photonic LED) devices.

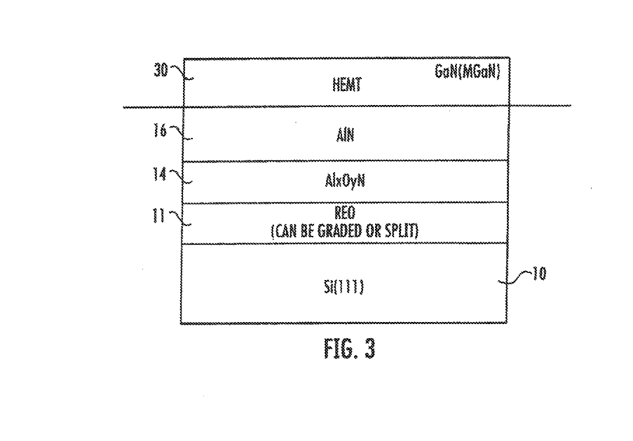

Turning to FIG. 3, template 12 is illustrated with a HEMT structure 30 formed thereon. Structure 30 is illustrated as a single layer for convenience but it should be understood that HEMT structure 30 includes the growth of one or more typical layers, including for example, i-GaN, AlN, AlGaN, GaN, and other inter-layers used in the formation and performance of HEMT devices.

One important embodiment for the REO/aluminum oxide/aluminum nitride template described above is the formation of a DBR as the REO in the template. This is especially true when forming a LED or other photonic device in or on the final III-N layer. It is known in the semiconductor industry that the fabrication of LEDs on silicon substrates is the most efficient because of the expense and wide use and established technology in the use of silicon. However, as stated above, it is also known that LED devices built on silicon substrates suffer from absorption of emitted light by the silicon substrate. LEDs emit light in all directions and any light directed at the silicon substrate is substantially lost since it is absorbed by the silicon substrate. Prior art has placed reflective surfaces on one side of the LED and removed the substrate so that substantially all light is emitted in one direction. This however is a very tedious and work intensive process.

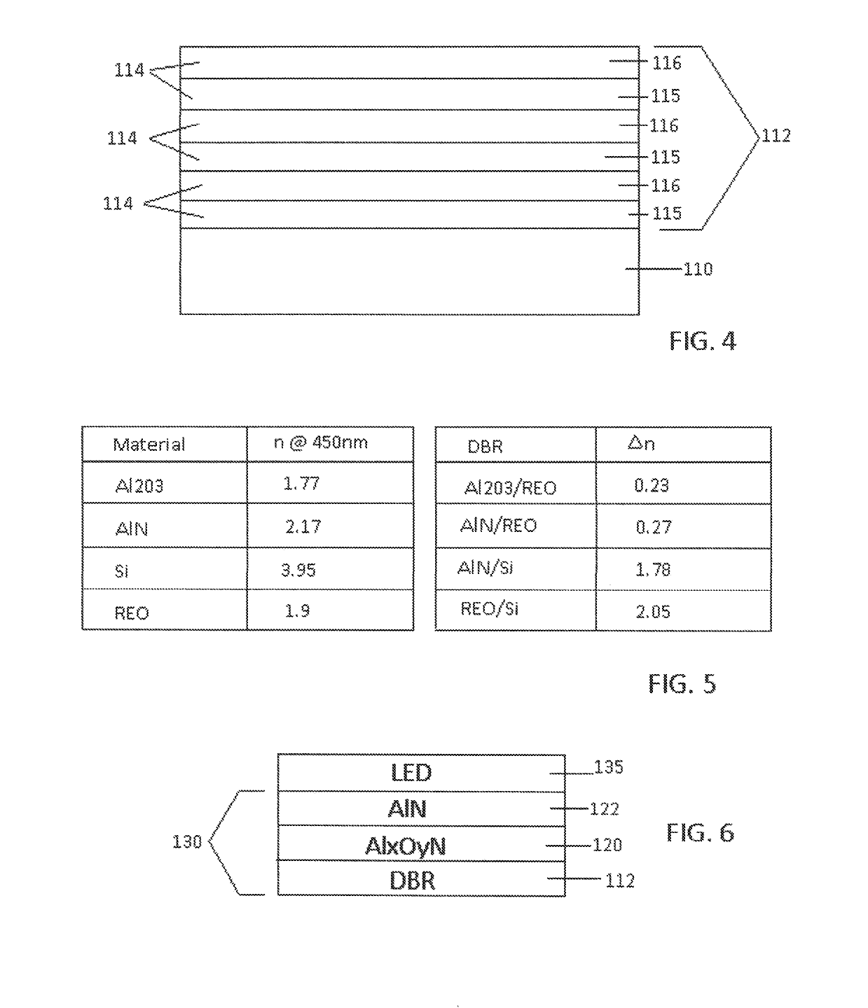

Turning to FIG. 4, a simplified layer diagram is illustrated of a Distributed Bragg Reflector (DBR) 112 on a silicon substrate 110, in accordance with the present invention. It will be understood that substrate 110 is or may be a standard well known single crystal wafer or portion thereof generally known and used in the semiconductor industry. Single crystal substrates, it will be understood, are not limited to any specific crystal orientation but could include (111) silicon, (110) silicon, (100) silicon or any other orientation or variation known and used in the art. The Si (100) and (111) substrates could also include various miscuts with nominal value between 0 and 10° in any direction. In the present invention a (111) silicon single crystal substrate is preferred because of the simplicity of further epitaxial growth.

As is known in the art, DBRs consist of a plurality of pairs of layers of material, with each pair forming a partial mirror that reflects some of the light incident upon it. In FIG. 1, DBR 112 is illustrated as having three pairs 114 with each pair including layers 115 and 116. Reflection or the mirror effect is produced by choosing the materials of layers 115 and 116 with a substantial difference in the refractive indices. Also, the number of pairs 114 are chosen to provide the most overall reflection for the most efficient, inexpensive or practical device.

Referring additionally to the chart of FIG. 5, the index of refraction for several materials are included with the index of refraction at 450 nm (the general wavelength of light for LEDs formed from III-N materials). Also illustrated in the chart of FIG. 5 is the difference in refractive indices for some pairs of the materials. From the materials included, it was determined that pairs of rare earth oxide and silicon (REO/Si) layers provide the largest refractive index difference (2.05) and therefore provide the best DBR pair.

Generally layers 115 and 116 are grown epitaxially on silicon substrate 110 and on each other as layers of single crystal material. Various rare earth oxides have a crystal lattice spacing that can be substantially matched to silicon with very little strain. For example, Gd₂O₃ has a crystal lattice spacing (a) of 10.81 Å, Er₂O₃ has a crystal lattice spacing (a) of 10.55 Å, Nd₂O₃ has a crystal lattice spacing (a) of 11.08 Å, and silicon has a double spacing (2a) of 10.86 Å. Thus, REOa˜Si2a herein defined as a “substantial crystallographic match”. Further, the crystal lattice spacing of the REO layers can be varied by varying the composition of the constituents.

Because the REO layers and the Si layers are substantially lattice matched, the first and last layers of DBR 112 can be either a REO layer or a Si layer. Also, it should be noted that because the Si layers in DBR 112 are very thin very little impinging light will be absorbed. In the example illustrated, pairs 114 of layers 115 and 116 are repeated three times, which forms a DBR mirror that is highly effective (90% of incident light is reflected) due to the larger refractive index difference between REO and silicon. It will be understood that more or fewer pairs 114 can be incorporated if a greater or lesser effective reflection is desired.

Turning to FIG. 6, a layer 120 of aluminum oxide is grown on the upper surface of DBR 112. Aluminum oxide layer 120 is grown epitaxially and is mostly single crystal material substantially crystal lattice matched to the upper layer of DBR 112. It will be understood that Al₂O₃ is the normal proportion required (stoichiometric) but non-stoichiometric compounds (e.g. Al₂₋ₓO_{3-y}) may be used in specific applications. Also, aluminum oxide layer 120 may include aluminum oxynitride (AlₓO_{y}N), which is intended to come within the definition of “aluminum oxide” for purposes of this invention.

While aluminum oxide can be grown on DBR 112, in some specific applications it may be desirable to include a graded or stepped layer of REO with an upper material having a lattice spacing more closely matching the lattice spacing of aluminum oxide, as explained in more detail above.

It should be noted that REO materials and aluminum oxide are impervious to MBE process gasses, i.e. N₂ plasma, NH₃ and metallic Ga, which is the preferred growth process in this invention. Also, in the event that other growth processes are used, such as the MOCVD process, the aluminum oxide is also impervious to MOCVD process gasses (NH₃, H₂, TMGa, etc.). Reaction of silicon with process gasses usually results in etching of silicon (H₂), formation of nitrides (NH₃), or severe reaction and blistering (Ga precursors). Thus silicon substrate 110 is protected from damage caused by generally all growth process gasses by both the REO layers and aluminum oxide layer 120. Preferably, aluminum oxide layer 120 is a few nanometers (nm) thick but for certain applications thicker or thinner films can be grown. Also, aluminum oxide layer 20 can be formed with a single continuous composition or it can be graded, in linear, stepwise or any similar schemes to aid in relief of stress.

An aluminum nitride (AlN) layer 122 is epitaxially grown on aluminum oxide layer 120 preferably by an MBE process. The combination of aluminum oxide layer 120 and aluminum nitride layer 122 results in a base for the further growth of III-N materials. DBR 112, aluminum oxide layer 120, and aluminum nitride layer 122 form template 130 which substantially crystal lattice matches the III-N materials to the silicon substrate and greatly reduces any thermal mismatch. Also, template 130 imparts chemical stability to the process due to the nature of the materials.

Template 130 is illustrated with a III-N LED structure 135 formed thereon. Structure 135 is illustrated as a single layer for convenience but it should be understood that III-N LED structure 135 is any convenient LED and may include for example the epitaxial growth of one or more typical layers i-GaN, n-GaN, active layers such as InGaN/GaN, electron blocking layers, p-GaN, and other inter-layers used in the formation and performance of LED devices. As explained above, III-N LED structure 135 will emit light downwardly as well as upwardly in FIG. 6. However, DBR 112 will intercept the downwardly emitted light and reflect it back upwardly so that the efficiency of LED 135 is substantially improved.

Because pairs 114 of layers 115 and 116 of DBR 112 are substantially crystal lattice matched to substrate 110 and because aluminum oxide layer 120, aluminum nitride layer 122 and LED 135 are all formed of single crystal material substantially crystal lattice matched to reduce strain, the entire structure can be easily and conveniently grown epitaxially and in many instances in a continuous growth process. Therefore, incorporating DBR 112 into the structure is relatively inexpensive and simple, compared to prior art methods and apparatus.

Thus, new and improved methods for the formation of a DBR/aluminum oxide/aluminum nitride template on a silicon substrate are disclosed. The main purpose of the DBR is to reflect light from an LED grown on the template upwardly so the light is not absorbed in silicon substrate 10. The new and improved methods for the formation of the template include incorporating the growth of the DBR into the normal fabrication of the LED and eliminating or greatly reducing the problem of possibly damaging the silicon substrate with subsequent process gasses. The invention also includes a new and improved DBR/aluminum oxide/aluminum nitride template on a silicon substrate with strain engineering to mitigate stresses formed during growth of III-N materials. Because of the strain engineering, new and improved LED structures can be substantially lattice matched and thermally matched by the new template on a silicon substrate.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A III-N template on a silicon substrate comprising:
a single crystal silicon substrate;
a Distributed Bragg Reflector positioned on the silicon substrate, the Distributed Bragg Reflector being substantially crystal lattice matched to the surface of the silicon substrate;
an aluminum oxide layer positioned on the surface of the Distributed Bragg Reflector, the aluminum oxide layer being substantially crystal lattice matched to the surface of the Distributed Bragg Reflector; and
a layer of aluminum nitride (AlN) positioned on the surface of the aluminum oxide layer and substantially crystal lattice matched to the surface of the aluminum oxide layer.

2. The III-N template on a silicon substrate as claimed in claim 1 further including a single crystal layer of rare earth oxide positioned between the Distributed Bragg Reflector and the aluminum oxide layer, the single crystal layer of rare earth oxide having a composition including multiple rare earth oxides one of graded to bridge the multiple rare earth oxides or stepped to have an abrupt change in the rare earth oxides.

3. The III-N template on a silicon substrate as claimed in claim 2 wherein the composition including multiple rare earth oxides includes a first rare earth oxide adjacent the Distributed Bragg Reflector having a crystal lattice spacing substantially matching the lattice spacing of an upper surface of the Distributed Bragg Reflector of silicon and a second rare earth oxide adjacent the aluminum oxide layer having a crystal lattice spacing substantially matching a crystal lattice spacing of the aluminum oxide layer.

4. The III-N template on a silicon substrate as claimed in claim 1 wherein the Distributed Bragg Reflector includes alternate layers of single crystal rare earth oxide and single crystal silicon.

5. The III-N template on a silicon substrate as claimed in claim 1 wherein the Distributed Bragg Reflector includes three pairs of layers of alternating rare earth oxide and silicon.

6. The III-N template on a silicon substrate as claimed in claim 1 further including an LED positioned on the layer of aluminum nitride, the LED including at least one III-N layer substantially crystal lattice matched to the surface of the aluminum nitride layer.

7. The III-N template on a silicon substrate as claimed in claim 6 wherein the LED includes one or more layers of i-GaN, n-GaN, active layers, electron blocking layers, p-GaN, and inter-layers.

8. A III-N structure on a silicon substrate comprising:
a single crystal silicon substrate;
a Distributed Bragg Reflector positioned on the silicon substrate, the Distributed Bragg Reflector being substantially crystal lattice matched to the surface of the silicon substrate and including three pairs of alternating layers of single crystal REO and single crystal silicon;
an aluminum oxide layer positioned on the surface of the Distributed Bragg Reflector, the aluminum oxide layer being substantially crystal lattice matched to the surface of the Distributed Bragg Reflector;
a layer of aluminum nitride (AlN) positioned on the surface of the aluminum oxide layer and substantially crystal lattice matched to the surface of the aluminum oxide layer; and
a III-N LED structure positioned on the layer of aluminum oxide, the III-N LED structure including at least one III-N layer substantially crystal lattice matched to the surface of the aluminum nitride layer.

9. A method of fabricating a template on a silicon substrate comprising the steps of:
providing a single crystal silicon substrate;
epitaxially growing a Distributed Bragg Reflector on the silicon substrate, the Distributed Bragg Reflector being substantially crystal lattice matched to the surface of the silicon substrate;
epitaxially growing an aluminum oxide layer on the surface of the Distributed Bragg Reflector, the aluminum oxide layer being substantially crystal lattice matched to the surface of the Distributed Bragg Reflector; and
epitaxially growing a layer of aluminum nitride (AlN) on the surface of the aluminum oxide layer substantially crystal lattice matched to the surface of the aluminum oxide layer.

10. A method as claimed in claim 9 wherein the step of epitaxially growing a Distributed Bragg Reflector includes growing alternate layers of single crystal REO and single crystal silicon.

11. A method as claimed in claim 10 wherein the step of epitaxially growing the alternate layers of single crystal REO and single crystal silicon includes growing at least three pairs of layers of single crystal REO and single crystal silicon.

12. The method as claimed in claim 9 further including a step of epitaxially growing an LED on the layer of aluminum nitride, the LED including at least one layer of III-N material substantially crystal lattice matched to the surface of the aluminum nitride layer.

13. The method as claimed in claim 12 wherein the step of epitaxially growing the LED includes epitaxially growing one or more layers of i-GaN, n-GaN, active layers, electron blocking layers, p-GaN, and inter-layers.

14. A method as claimed in claim 9 wherein the step of epitaxially growing the aluminum oxide layer includes depositing a layer of aluminum oxide with one of a single continuous composition or a linear or stepwise graded composition.

15. A method as claimed in claim 9 wherein the step of epitaxially depositing the layer of aluminum nitride includes depositing the layer of aluminum nitride by an MBE process.

16. A method as claimed in claim 9 wherein the step of epitaxially growing the aluminum oxide layer includes depositing aluminum oxynitride.

17. A method of fabricating a III-N structure on a silicon substrate comprising the steps of:
providing a single crystal silicon substrate;
epitaxially growing a Distributed Bragg Reflector on the silicon substrate, the Distributed Bragg Reflector being substantially crystal lattice matched to the surface of the silicon substrate and including three pairs of alternating layers of single crystal REO and single crystal silicon;
epitaxially growing an aluminum oxide layer on the surface of the Distributed Bragg Reflector, the aluminum oxide layer being substantially crystal lattice matched to the surface of the Distributed Bragg Reflector;
epitaxially growing a layer of aluminum nitride (AlN) on the surface of the aluminum oxide layer substantially crystal lattice matched to the surface of the aluminum oxide layer; and epitaxially growing a III-N LED structure on the layer of aluminum oxide, the III-N LED structure including at least one III-N layer substantially crystal lattice matched to the surface of the aluminum nitride layer.

18. The method as claimed in claim 17 wherein the step of epitaxially growing the III-N LED structure includes epitaxially growing one or more layers of i-GaN, n-GaN, active layers, electron blocking layers, p-GaN, and inter-layers.

19. A method as claimed in claim 17 wherein the step of epitaxially growing the aluminum oxide layer includes depositing a layer of aluminum oxide with one of a single continuous composition or a linear or stepwise graded composition.

20. A method as claimed in claim 17 wherein the step of epitaxially depositing the layer of aluminum nitride includes depositing the layer of aluminum nitride by an MBE process.

21. A method as claimed in claim 17 wherein the step of epitaxially growing the aluminum oxide layer includes depositing aluminum oxynitride.
